(19) United States
(12) Patent Application Publication
(10) Pub. No.: US 2023/0299009 A1
(43) Pub. Date: Sep. 21, 2023

(54) ELECTRONIC DEVICE

(71) Applicant: STMicroelectronics (Crolles 2) SAS, Crolles (FR)

(72) Inventors: Fady ABOUZEID, La Terrasse (FR); Philippe ROCHE, Biviers (FR)

(73) Assignee: STMicroelectronics (Crolles 2) SAS, Crolles (FR)

(21) Appl. No.: 18/120,555

(22) Filed: Mar. 13, 2023

(30) Foreign Application Priority Data
Mar. 17, 2022 (FR) 2202331

(51) Int. Cl. H01L 23/538; H01L 21/768

(52) U.S. Cl. CPC H01L 23/5386; H01L 23/5385; H01L 21/76864

(57) ABSTRACT

An electronic device includes a first electronic chip, a second electronic chip, and an interconnection circuit. A first region of a first surface of the first electronic chip is assembled by hybrid bonding to a third region of a third surface of the interconnection circuit. A second region of a second surface of the second electronic chip is assembled by hybrid to a fourth region of the third surface of the interconnection circuit. In this configuration, the first electronic chip is electrically coupled to the second electronic chip through the interconnection circuit. The first surface of the first electronic chip further includes a fifth region which is not in contact with the interconnection circuit. This fifth region includes a connection pad electrically connected by a connection element to a connection substrate to which the interconnection circuit is mounted.

### PRIORITY CLAIM

This application claims the priority benefit of French Application for Patent No. 2202331, filed on Mar. 17, 2022, the content of which is hereby incorporated by reference in its entirety to the maximum extent allowable by law.

### TECHNICAL FIELD

The present disclosure generally concerns electronic devices and their associated manufacturing methods.

### BACKGROUND

To comply with Moore's law concerning the juxtaposition or the stacking of a number of heterogeneous electronic chips per surface area unit, an implemented solution is the use, for example, of an interconnection substrate having the chips assembled thereon, the substrate being provided with through silicon vias (TSV). However, the use of these through silicon vias is a problem since it generates limitations, particularly in radio frequency applications, and their implementation is expensive. Other limitations of through silicon vias are linked to the loss of usable surface area due to the surface covered by the through silicon vias and also the need to adapt the connection pitches to the size of the through silicon vias.

There exists a need to integrate a plurality of chips having, for example, heterogeneous functions, without using through silicon vias and while limiting manufacturing costs.

There is a need in the art to overcome all or part of the disadvantages of known electronic devices.

### SUMMARY

An embodiment provides an electronic device. comprising: a first electronic chip and a second electronic chip; and an interconnection circuit comprising a first planar surface; a first region of a first surface of the first electronic chip being assembled by hybrid bonding to a first region of the first surface of the interconnection circuit, a first region of a first surface of the second electronic chip being assembled by hybrid bonding to a second region of the first surface of the interconnection circuit so that the first electronic chip is electrically coupled to the second electronic chip through the interconnection circuit; the first surface of the first electronic chip further comprising a second region which is not in contact with the interconnection circuit and comprising at least one connection pad.

An embodiment provides a method of manufacturing an electronic device that comprises: a first electronic chip and a second electronic chip; and an interconnection circuit comprising a first planar surface. A first region of a first surface of the first electronic chip is assembled by hybrid bonding to a first region of the first surface of the interconnection circuit. A first region of a first surface of the second electronic chip is assembled by hybrid bonding to a second region of the first surface of the interconnection circuit so that the first electronic chip is electrically coupled to the second electronic chip through the interconnection circuit. In this configuration, the first surface of the first electronic chip further comprises a second region which is not in contact with the interconnection circuit and comprises at least one connection pad.

An embodiment provides a method of manufacturing an electronic device comprising: providing a first electronic chip, a second electronic chip, and a connection circuit comprising a first planar surface; assembling, by hybrid bonding, a first region of a first surface of the first electronic chip to a first region of the first surface of the interconnection circuit; and assembling, by hybrid bonding, a first region of a first surface of the second electronic chip to a second region of the first surface of the interconnection circuit so that the first electronic chip is electrically connected to the second electronic chip through the interconnection circuit; wherein the first surface of the first electronic chip further comprises a second region which is not in contact with the interconnection circuit and comprises at least one connection pad.

According to an embodiment, the first and second electronic chips as well as the connection circuit comprise a substrate and conductive tracks. The conductive tracks of the first electronic chip are arranged over a plurality of levels and comprise at least one connection element arranged on the first surface of the first region of the first electronic chip. The conductive tracks of the second electronic chip are arranged over a plurality of levels and comprise at least one connection element arranged on the first region of the first surface of the second electronic chip. The conductive tracks of the interconnection circuit comprise at least one connection element arranged on the first and second regions of the first surface of the interconnection circuit. The connection element of at least one of the conductive tracks of the first region of the first electronic chip is in contact with the connection element of at least one of the conductive tracks of the first region of the interconnection circuit, and the connection element of at least one of the conductive tracks of the first region of the second electronic chip is in contact with the connection element of at least one of the conductive tracks of the second region of the interconnection circuit.

According to an embodiment, the first electronic chip comprises one or a plurality of active or passive components coupled to the conductive tracks of the first electronic chip. The connection element of the conductive tracks of the second electronic chip is at least partly surrounded with an insulator. The second electronic chip comprises one or a plurality of active or passive components coupled to the conductive tracks of the second electronic chip, wherein the connection element of the conductive tracks of the second electronic chip is at least partly surrounded with an insulator. The interconnection circuit comprises one or a plurality of active or passive components coupled to the conductive tracks of the interconnection circuit, and the connection element of the conductive tracks of the interconnection circuit is at least partly surrounded with an insulator.

According to an embodiment, the assembly by hybrid bonding of the first region of the first surface of the first electronic chip to the first region of the first surface of the interconnection circuit is performed: between the connection element of at least one of the conductive tracks of the first region of the first surface of the first electronic chip and the connection element of at least one of the conductive tracks of the first region of the first surface of the interconnection circuit. Additionally, or alternatively, the assembly by hybrid bonding is performed between the insulator surrounding the connection element of said at least one of the conductive tracks of the first region of the first surface of the first electronic chip and the insulator surrounding the connection element of said at least one of the conductive tracks of the first region of the first surface of the interconnection circuit. According to an embodiment, the assembly by hybrid bonding of the first region of the second electronic chip to the second region of the interconnection circuit is performed: between the connection element of at least one of the conductive tracks of the first region of the first surface of the second electronic chip and the connection element of at least one of the conductive tracks of the second region of the first surface of the interconnection circuit. Additionally, or alternatively, the assembly by hybrid bonding is performed between the insulator surrounding the connection element of said at least one of the conductive tracks of the first region of the first surface of the second electronic chip and the insulator surrounding the connection element of said at least one of the conductive tracks of the second region of the first surface of the interconnection circuit.

According to an embodiment, the interconnection circuit has a thickness smaller than or equal to 100 micrometers.

According to an embodiment, the first electronic chip and the second electronic chip are flipped chips.

According to an embodiment, the electronic device comprises a connection substrate comprising one or a plurality of connection pads arranged at the level of a contact surface of the connection substrate, one or a plurality of electric coupling elements connecting the connection pad(s) of the second region of the first electronic chip to the connection pads of the connection substrate.

According to an embodiment, the first surface of the second electronic chip further comprises a second region which is not in contact with the interconnection circuit and which comprises at least one connection pad arranged at the level of the first surface of the second electronic chip.

According to an embodiment, the substrate of the interconnection circuit is in contact with the contact surface of the connection substrate.

According to an embodiment, prior to the hybrid bonding assembly step, the first and the second electronic chip are held fixed on a transfer substrate and, subsequently to the hybrid bonding assembly step, the first and the second electronic chip are separated from said transfer substrate.

According to an embodiment, in a connection step, said at least one of the connection pads of the second region of the first surface of the first electronic chip is placed into contact, by a thermal and/or mechanical treatment, with an end of one of the electric coupling elements, and said electric coupling element is placed into contact, with said treatment, with one of the connection pads of the connection substrate.

According to an embodiment, in the connection step, said at least one of the connection pads of the second region of the first surface of the second electronic chip is placed into contact, by a thermal and/or mechanical treatment, with an end of one of the electric coupling elements, and another end of said electric coupling element is placed into contact, with said treatment, with another one of the connection pads of the connection substrate.

According to an embodiment, prior to the connection step, the assembly formed by the first electronic chip, the second electronic chip, and the interconnection circuit is flipped so that the interconnection circuit is on the side of the connection substrate and so that the connection pads of the first and second electronic chips are oriented towards the connection substrate.

According to an embodiment, the device comprises another interconnection circuit comprising a first planar surface and a third electronic chip; a first region of the third electronic chip being assembled by hybrid bonding to a first region of the first surface of the other interconnection circuit; the second region of the first electronic chip being assembled by hybrid bonding to a second region of the first surface of the other interconnection circuit so that the first electronic chip is electrically coupled to the third electronic chip through the other interconnection circuit.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an electronic device according to an embodiment of the present disclosure;

FIG. 2 shows an electronic device according to another embodiment of the present disclosure;

FIG. 3 shows a method of manufacturing the electronic devices of FIGS. 1 and 2; and

FIG. 4 is a simplified enlarged cross-section view of a device according to another embodiment of the present disclosure.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. For example, methods of molecular or hybrid or direct bonding between integrated circuits are known by those skilled in the art and will not be described in detail herein.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

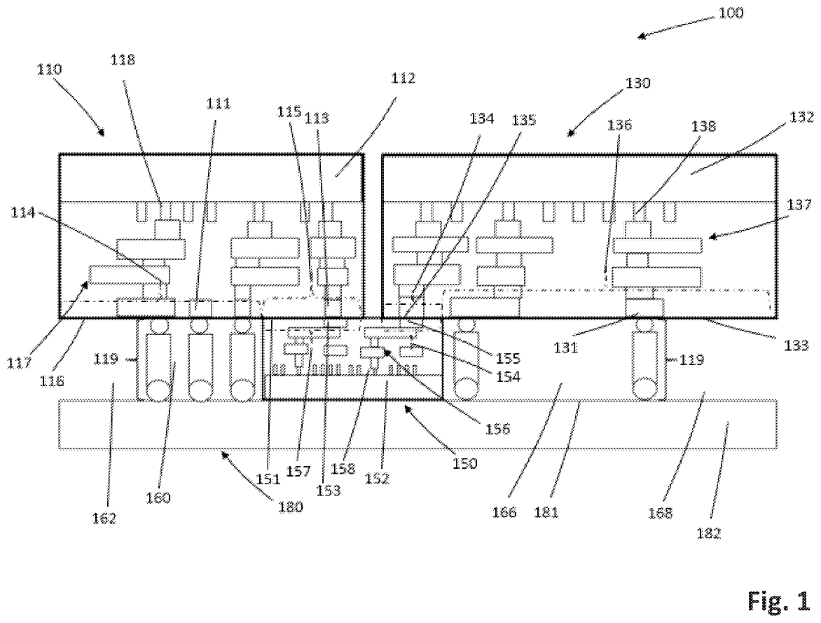

FIG. 1 shows an electronic device 100 according to an embodiment of the present disclosure. Electronic device 100 comprises a first electronic integrated circuit chip 110 and a second electronic integrated circuit chip 130. The first and second chips 110, 130 each comprise, for example, a substrate 112, 132, electronic tracks 117, 137, and active or passive components 118, 138. Substrates 112, 132 are, for example, made of a semiconductor material such as silicon. Electronic tracks 117, 137 are, for example, stacked over a plurality of interconnection levels and they are coupled to components 118, 138. In an example, the first and second chips 110, 130 are chips of flip chip type.

Electronic device 100 further comprises, for example, an interconnection integrated circuit 150 comprising, for example, a first planar surface 151. Interconnection circuit 150 comprises, for example, a substrate 152 which is, for example, semiconductor, electronic tracks 156, and, optionally, active or passive components 158. Electronic tracks 156 are, for example, stacked over a plurality of interconnection levels and, for example, coupled to components 158. The electronic tracks 156 of interconnection circuit 150 comprise, for example, at least one connection element 153 arranged on the first surface 151 of interconnection circuit 150. Connection elements 153 are, for example, flush, and with a planar surface, and are compatible with a hybrid bonding or a placing in direct contact with one of connection elements 113.

First electronic chip 110 comprises, for example, a first region 115 of a first surface 116, first region 115 being in contact with a first region 157 of the surface 151 of interconnection circuit 150. For example, the first region 115 of first electronic chip 110 is assembled by hybrid bonding to the first region 157 of interconnection circuit 150. A hybrid bonding between two surfaces corresponds to a bonding both between metal portions of each surface, such as connection elements, and between insulator portions surrounding the metal portions.

Second electronic chip 130 comprises, for example, a first region 134 of a first surface 133, first region 134 being, for example, assembled by hybrid bonding to a second region 154 of the first surface 151 of interconnection circuit 150. Thereby, first electronic chip 110 is, for example, electrically coupled to second electronic chip 130 via interconnection circuit 150. In an example, not illustrated, this enables to form a direct electric connection between the interconnection network 117 of chip 110, to interconnection network 137 in chip 130, through the conductive tracks 157 of interconnection circuit 150, without passing through the active/passive devices 158 of interconnection circuit 150. The first surfaces 116, 133 of the first and second chips 110, 130 are, for example, located on same horizontal plane. First and second chips 110, 130 have, for example, the same height, each chip 110, 130 comprising, for example, a second surface opposite to their first surface, the second surfaces of the first and second chips 110, 130 are, for example, on a same horizontal plane. However, it will also be possible for the first and second chips 110, 130 to have different heights with respect to each other. First and second chips 110, 130 are, due to the bonding, rigidly attached to connection circuit 150. This allows a manipulation of the assembly resulting from the hybrid bonding.

The electronic tracks 117 of first electronic chip 110 comprise, for example, at least one connection element 113 arranged on the first surface 116 of the first region 115 of the first electronic chip 110. Connection element 113 is, for example, flush with the surface and allows a contacting from the outside of the chip. The electronic tracks 137 of second electronic chip 130 comprise, for example, at least one connection element 135 arranged on the first surface 133 of the first region 134 of first electronic chip 130. The electronic chips 156 of interconnection circuit 150 comprise, for example, at least one connection element 155 arranged on the first surface 151 of interconnection circuit 150. Connection elements 155 are, for example, flush and with a planar surface, and are compatible with a hybrid bonding or a direct placing in contact with one of the connection elements 135 of second chip 130. The connection elements 113, 135 of the conductive tracks of the first and of the second electronic chip 110, 130 as well as those 153, 155 of interconnection circuit 150 are, for example, at least partly surrounded with an insulator. In an example, this insulator is the same for the first and second chips 110, 130 as well as for interconnection circuit 150. This allows an optimal hybrid bonding. The insulator is, for example, silicon oxide or a low-permittivity (low-k) insulator.

Connection elements 113, 135, 153, and 155 are, for example, connection pads and/or planar conductive surfaces and/or surfaces having undergone a surface preparation to make then adapted to a hybrid bonding. This surface preparation step comprises, for example, a chemical-mechanical polishing and/or cleaning and/or of a chemical surface activation to improve the adhesion thereof.

According to an embodiment, the assembly by hybrid bonding of the first region 115 of the first surface 116 of the first electronic chip 110 to the first region 157 of the first surface 151 of interconnection circuit 150 is performed between the connection element 113 of at least one of the conductive tracks of the first region 115 of the first surface 116 of first electronic chip 110 and the connection element 153 of at least one of the conductive tracks of the first region 157 of the first surface of interconnection circuit 150. The hybrid bonding is, for example, performed between the insulator surrounding the connection element 113 of at least one of the conductive tracks 117 of the first region 115 of the first surface 116 of first electronic chip 110 and the insulator surrounding the connection element 153 of at least one of the conductive tracks of the first region 157 of the first surface 151 of interconnection circuit 150. The insulator is, for example, submitted to a preparation prior to the hybrid bonding. This preparation may comprise a chemical-mechanical polishing and/or cleaning and/or of a chemical surface activation to improve the adhesion thereof.

According to an example, the assembly by hybrid bonding of the first region 134 of second electronic chip 130 to the second region 154 of interconnection circuit 150 is performed between the connection element 135 of at least one of the conductive tracks of the first region 134 of the first surface 133 of second electronic chip 130 and the connection element 155 of at least one of the conductive tracks of the second region 154 of the first surface of interconnection circuit 150. The hybrid bonding is, for example, performed between the insulator surrounding the connection element 135 and the insulator surrounding the connection element 155 of at least one of the conductive tracks of the second region 154 of the first surface 151 of interconnection circuit 150.

The use of the hybrid bonding enables to create reliable and high-quality contacts.

Such an electronic device 100 enables to connect two chips having, for example, heterogeneous functions without using through vias. The interconnection circuit 150 of FIG. 1 does not need to be greater than the two chips 110, 130, and this enables to limit manufacturing costs.

The first surface 133 of second electronic chip 130 comprises, for example, a second region 136 which is not in contact with interconnection circuit 150 and which comprises, for example, a plurality of connection pads 131. In an example, a single connection pad 131 may be envisaged. Connection pad(s) 131 are coupled, for example, to tracks 137. Connection pads 131 comprise, for example, one or a plurality of barrier layers such as, for example, titanium and/or tantalum nitrides. In an example, connection pads 131 are similar to connection pads 111.

According to the example of FIG. 1, electronic device 100 optionally comprises a connection substrate 180 which comprises, on a contact surface 181, for example, connection pads (not illustrated), for example, similar to the connection pads 111, 131 of the first or the second electronic chip 110, 130. The connection pads of substrate 180 are coupled, for example, to electric tracks (not illustrated) arranged, for example, in a routing substrate 182 of connection substrate 180. Electric coupling elements 119 connect, for example, the connection pads 111, 131 of the first and/or of the second electronic chip 110, 130 with the connection pads of connection substrate 180. Electric coupling elements 119 are formed, for example, of one or a plurality of conductive balls. In another example, electric coupling elements 119 comprise copper pillars or microbumps arranged on a connection pad (under bump metallurgy—UBM) at the chip surface, forming a solder pad, capable of being soldered to the connection pads provided at the surface of substrate 180. In an example, coupling elements 119 are formed by soldering between one or a plurality of conductive balls and a copper pillar, for example, by thermocompression or by thermal treatment.

In an example, not illustrated, a protection material (underfill) is implemented between first chip 110 and connection substrate 180. The underfill is present, for example, in spaces 160 comprised between electric coupling elements 119 and/or in spaces 162 between surfaces 116 and 181. The proportion of underfill used depends on the application and may be estimated by those skilled in the art in a search for a tradeoff between the mechanical robustness and the thermal performance, for example. The underfill is hardened, for example after liquid application, by an ultraviolet and/or thermal treatment.

In the example of FIG. 1, the semiconductor substrate 152 of interconnection circuit 150 is in contact with the contact surface 181 of connection substrate 180. This enables to ensure the stability of device 100.

It will be noted that the mounting of the back surface of semiconductor substrate 152 of interconnection circuit 150 to the front surface of the connection substrate 180 does not implicate the making of a direct electrical connection between interconnection circuit 150 and connection substrate 180. The electrical connection (for signals and power) for the interconnection circuit 150 to the connection substrate 180 is made through one or more of the first and second electronic chips 110, 130.

Furthermore, it will be noted that the interconnection circuit 150 is not, for example, in electrical contact with the connection substrate 180. Indeed, only the semiconductor substrate 152 of the interconnection circuit 150 is, for example, in contact with the connection substrate 180.

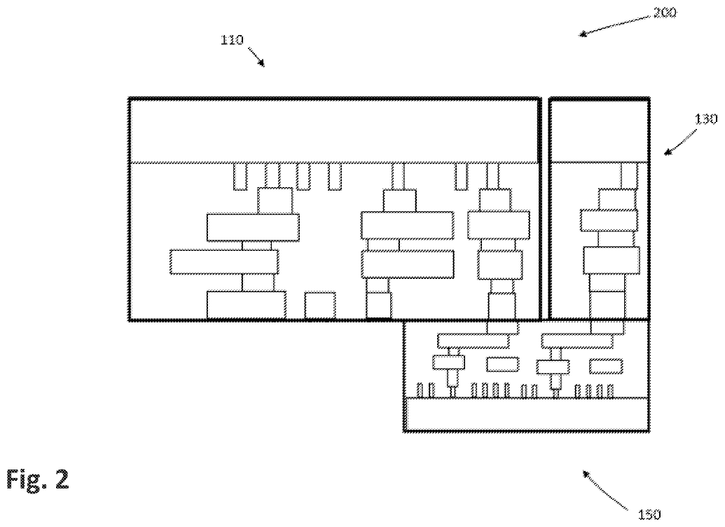

FIG. 2 shows an electronic device 200 according to another embodiment of the present disclosure.

Electronic device 200 is similar to device 100, except that second chip 130 does not exceed the width of interconnection circuit 150. In the example of FIG. 2, second electronic chip 130 comprises no second region 136 and also no connection pads 131. Second electronic chip 130 is thus not soldered or coupled to a connection substrate 180.

Connection substrate 180 is not illustrated in FIG. 2 but could be present and coupled to first chip 110 as in the device 100 of FIG. 1. It would also be possible for the devices 100, 200 of FIGS. 1 and 2 not to comprise substrate 180, and for connection pads 111, 131 to be coupled to other circuits for example by connection wires.

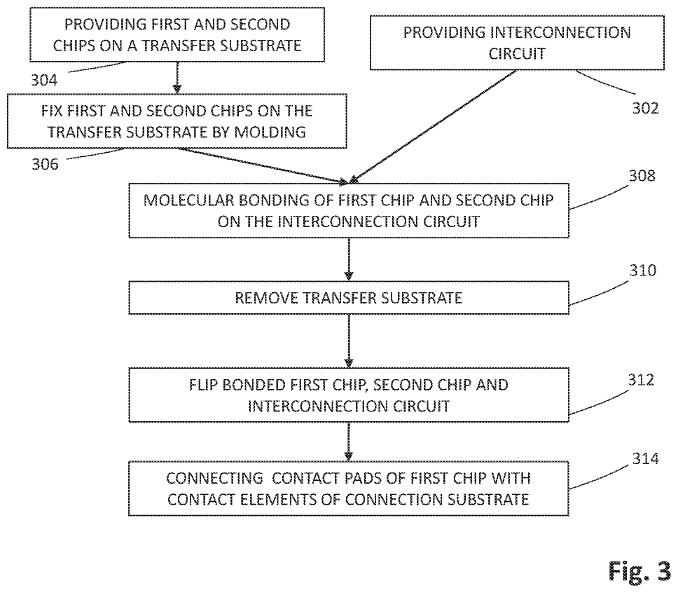

FIG. 3 shows a method of manufacturing the electronic devices of FIGS. 1 and 2.

At a step 302 (PROVIDING INTERCONNECTION CIRCUIT), connection circuit 150 is provided.

At a step 304 (PROVIDING FIRST AND SECOND CHIPS ON A TRANSFER SUBSTRATE), first electronic chip 110 and second electronic chip 130 are provided.

At a step 306 (FIX FIRST AND SECOND CHIPS ON THE TRANSFER SUBSTRATE BY MOLDING), which is optional, first electronic chip 110 and second electronic chip 130 are held fixed, for example side by side on a transfer substrate (not shown). This step may be carried out, for example, by depositing the first and second chips 110, 130 on the transfer substrate, and then by depositing a molding material to hold, after hardening, the two chips in place.

At a step 308 (MOLECULAR BONDING OF FIRST CHIP AND SECOND CHIP ON THE INTERCONNECTION CIRCUIT), the first and second chips 110, 130 are assembled by hybrid bonding to interconnection circuit 150.

At a step 310 (REMOVE TRANSFER SUBSTRATE), which is optional, the transfer substrate is separated from the first and second electronic chips 110, 130, for example by a laser or thermal or mechanical separation treatment, according to the considered temporary bonding material.

At a step 312 (FLIP ASSEMBLY OF FIRST CHIP, SECOND CHIP AND INTERCONNECTION CIRCUIT), which is optional, the assembly formed by first and second electronic chips 110, 130, which are molecularly bonded to interconnection circuit 150, is flipped.

At a step 314 (CONNECTING CONTACT PADS OF FIRST CHIP WITH CONTACT ELEMENTS OF CONNECTION SUBSTRATE), which is optional, the connection pads 111, 131 respectively of the first and of the second electronic chip 110, 130 are placed into contact, for example by soldering or by thermocompression or thermal treatment, with coupling elements 119, which are themselves placed into contact with the respective connection pads of connection circuit 180.

Such a method enables to limit manufacturing costs with a parallel treatment of the assembly, it further enables to improve the assembly accuracy.

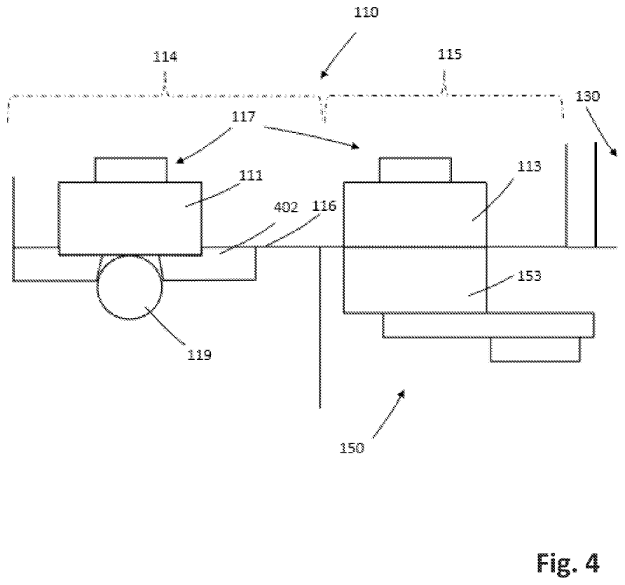

FIG. 4 shows a simplified enlarged cross-section view of device 100 according to another embodiment of the present disclosure. In the example of FIG. 4, the first and second electronic chips 110, 130 as well as interconnection circuit 150 are, for example, similar to those of FIG. 1 or 2. The view of FIG. 4 concentrates on the interface between first chip 110 and interconnection circuit 150.

In the example of FIG. 4, the tracks 117 of first chip 110 are coupled or connected, for example, to the connection pads 111 of the region 114 of first surface 116, and to the connection elements 113 of the region 115 of the first surface 116.

Connection pads 111 comprise, for example, one or a plurality of barrier layers (not illustrated) such as, for example, titanium and/or tantalum nitrides. An insulator layer 402 partly covers, for example, a surface of connection pads 111 arranged towards electric coupling element 119, while leaving, for example, an opening having coupling element 119 arranged thereon.

At the level of the first region 115 of first chip 110, at least one connection element 113 is flush, for example, with the surface and is capable of being in contact with the corresponding connection element 153 of interconnection circuit 150, which is arranged in front.

Thus, the surface 116 of chip 110 comprises both connection pads 111 capable of being connected to coupling elements, for example, balls or pillars, and connection elements 113 capable of being placed in direct contact, by hybrid bonding, with corresponding connection elements 153 of interconnection circuit 150.

A similar arrangement is implemented, for example, between second chip 130 and interconnection circuit 150.

Various embodiments and variants have been described. Those skilled in the art will understand that certain features of these various embodiments and variants may be combined, and other variants will occur to those skilled in the art. In particular, those skilled in the art may implement a number greater than 2 of electronic chips so that they are assembled with a hybrid bonding to a same interconnection circuit while being electrically connected together. In another case, the number of electronic chips is greater than 2 and they are assembled in a chain two by two with a distinct interconnection circuit between each assembled pair of chips.

In an example, the device for example comprises another interconnection circuit comprising a first planar surface and a third electronic chip. In this example, a first region of the third electronic chip is assembled by hybrid bonding to a first region of the first surface of the other interconnection circuit. In this example, the second region 114 of the first electronic chip is assembled by hybrid bonding to a second region of the first surface of the other interconnection circuit so that the first electronic chip is electrically connected to the third electronic chip through the other interconnection circuit. Such an example enables to easily interconnect a plurality of chips having several functions without having to use through vias.

Finally, the practical implementation of the described embodiments and variations is within the abilities of those skilled in the art based on the functional indications given hereabove.

1. An electronic device, comprising:
a first electronic chip having a first surface that includes a first region;
a second electronic chip having a second surface that includes a second region; and
an interconnection circuit comprising a third surface that includes a third region and a fourth region;
wherein the first region of the first surface of the first electronic chip is assembled by hybrid bonding to the third region of the third surface of the interconnection circuit,
wherein the second region of the second surface of the second electronic chip is assembled by hybrid bonding to the fourth region of the third surface of the interconnection circuit;
wherein the first electronic chip is electrically coupled to the second electronic chip through the interconnection circuit; and
wherein the first surface of the first electronic chip further comprises a fifth region which is not in contact with the interconnection circuit and comprises at least one connection pad.

2. The device according to claim 1:
wherein the first and second electronic chips as well as the interconnection circuit each comprise a substrate and conductive tracks;
wherein the conductive tracks of the first electronic chip are arranged over a plurality of levels and comprise at least one connection element arranged on the first surface of the first region of the first electronic chip;
wherein the conductive tracks of the second electronic chip are arranged over a plurality of levels and comprise at least one connection element arranged on the second region of the second surface of the second electronic chip; and
wherein the conductive tracks of the interconnection circuit comprise at least one connection element arranged on the third and fourth regions of the third surface of the interconnection circuit;
wherein the connection element of at least one of the conductive tracks of the first region of the first electronic chip is in contact with the connection element of at least one of the conductive tracks of the third region of the interconnection circuit; and
wherein the connection element of at least one of the conductive tracks of the second region of the second electronic chip is in contact with the connection element of at least one of the conductive tracks of the fourth region of the interconnection circuit.

3. The device according to claim 2, wherein:
the first electronic chip comprises one or a plurality of active or passive components coupled to the conductive tracks of the first electronic chip;
the connection element of the conductive tracks of the first electronic chip is at least partly surrounded with an insulator;
the second electronic chip comprises one or a plurality of active or passive components coupled to the conductive tracks of the second electronic chip;
the connection element of the conductive tracks of the second electronic chip is at least partly surrounded with an insulator;
the interconnection circuit comprises one or a plurality of active or passive components coupled to the conductive tracks of the interconnection circuit; and
the connection element of the conductive tracks of the interconnection circuit is at least partly surrounded with an insulator.

4. The device according to claim 3, wherein the assembly by hybrid bonding of the first region of the first surface of the first electronic chip to the third region of the third surface of the interconnection circuit is performed:
between the connection element of at least one of the conductive tracks of the first region of the first surface of the first electronic chip and the connection element of at least one of the conductive tracks of the third region of the third surface of the interconnection circuit; and
between the insulator surrounding the connection element of said at least one of the conductive tracks of the first region of the first surface of the first electronic chip and the insulator surrounding the connection element of said at least one of the conductive tracks of the third region of the third surface of the interconnection circuit.

5. The device according to claim 3, wherein the assembly by hybrid bonding of the second region of the second electronic chip to the fourth region of the interconnection circuit is performed:
between the connection element of at least one of the conductive tracks of the second region of the second surface of the second electronic chip and the connection element of at least one of the conductive tracks of the fourth region of the third surface of the interconnection circuit; and
between the insulator surrounding the connection element of said at least one of the conductive tracks of the second region of the second surface of the second electronic chip and the insulator surrounding the connection element of said at least one of the conductive tracks of the fourth region of the third surface of the interconnection circuit.

6. The device according to claim 1, wherein the interconnection circuit has a thickness smaller than or equal to 100 micrometers.

7. The device according to claim 1, wherein the first electronic chip and the second electronic chip are flipped chips.

8. The device according to claim 1, wherein the electronic device further comprises:
a connection substrate comprising one or a plurality of connection pads arranged at the level of a contact surface of the connection substrate; and
an electric coupling element connecting the connection pad of the fifth region of the first electronic chip to the connection pad of the connection substrate.

9. The device according to claim 8, wherein the second surface of the second electronic chip further comprises a sixth region which is not in contact with the interconnection circuit and which comprises at least one connection pad arranged at the level of the second surface of the second electronic chip.

10. The device according to claim 8, wherein the substrate of the interconnection circuit is mounted to the contact surface of the connection substrate.

11. The device according to claim 10, wherein the substrate of the interconnection circuit is made of a semiconductor material.

12. The device according to claim 11, wherein mounting of the substrate of the interconnection circuit to the contact surface of the connection substrate does not make a direct electrical connection between the interconnection circuit and the connection substrate.

13. The device according to claim 1, further comprising:
a further interconnection circuit comprising a further surface and a third electronic chip;
wherein a region of the third electronic chip is assembled by hybrid bonding to a first further region of the further surface of the further interconnection circuit;
wherein the fifth region of the first electronic chip is assembled by hybrid bonding to a second further region of the further surface of the further interconnection circuit,
wherein the first electronic chip is electrically coupled to the third electronic chip through the further interconnection circuit.

14. A method of manufacturing an electronic device, comprising:
providing a first electronic chip having a first surface that includes a first region and a fifth region;
providing a second electronic chip having a second surface that includes a second region;
providing a connection circuit having a third surface that includes a third region and a fourth region;
assembling, by hybrid bonding, the first region of the first surface of the first electronic chip to the third region of the third surface of the interconnection circuit;
assembling, by hybrid bonding, the second region of the second surface of the second electronic chip to the fourth region of the third surface of the interconnection circuit;
wherein the first electronic chip is electrically coupled to the second electronic chip through the interconnection circuit; and
wherein the fifth region of the first surface of the first electronic chip is not in contact with the interconnection circuit and comprising at least one connection pad.

15. The method according to claim 14, wherein hybrid bonding the first region of the first surface of the first electronic chip to the third region of the third surface of the interconnection circuit comprises:
bonding a connection element of conductive tracks of the first electronic chip and a connection element of conductive tracks of the interconnection circuit; and
bonding an insulator surrounding the conductive tracks of the first electronic chip and an insulator surrounding the conductive tracks of the interconnection circuit.

16. The method according to claim 14, wherein hybrid bonding the second region of the second surface of the second electronic chip to the fourth region of the third surface of the interconnection circuit comprises:
bonding a connection element of conductive tracks of the second electronic chip and a connection element of conductive tracks of the interconnection circuit; and
bonding an insulator surrounding the conductive tracks of the second electronic chip and an insulator surrounding the conductive tracks of the interconnection circuit.

17. The method according to claim 14, wherein the interconnection circuit has a thickness smaller than or equal to 100 micrometers.

18. The method according to claim 14, wherein the first electronic chip and the second electronic chip are flipped chips.

19. The method according to claim 14, further comprising:
providing a connection substrate comprising connection pads arranged at the level of a contact surface of the connection substrate;
using electric coupling elements to connecting the connection pads of the fifth region of the first electronic chip to the connection pads of the connection substrate.

20. The method according to claim 19, further comprising mounting a substrate of the interconnection circuit to the contact surface of the connection substrate.

21. The method according to claim 20, wherein the substrate of the interconnection circuit is made of a semiconductor material.

22. The method according to claim 21, wherein mounting of the substrate of the interconnection circuit to the contact surface of the connection substrate does not make a direct electrical connection between the interconnection circuit and the connection substrate.

23. The method according to claim 14, further comprising, prior to the hybrid bonding, holding the first and second electronic chips fixed on a transfer substrate, performing the hybrid bonding with the first and second electronic chips fixed on the transfer substrate, and, subsequent to the hybrid bonding, separating the first and the second electronic chip from said transfer substrate.

24. The method according to claim 14, further comprising:
placing a connection pad of the fifth region of the first surface of the first electronic chip into contact, by a thermal and/or mechanical treatment, with an end of an electric coupling element; and
placing another end of said electric coupling element into contact, by a thermal and/or mechanical treatment, with a connection pad of a connection substrate to which the interconnection circuit is mounted.

25. The method according to claim 24, further comprising:
placing a connection pad of a sixth region of the second surface of the second electronic chip into contact, by a thermal and/or mechanical treatment, with an end of an electric coupling element; and
placing another end of said electric coupling element into contact, by a thermal and/or mechanical treatment, with another connection pad of the connection substrate to which the interconnection circuit is mounted.

26. The method according to claim 24, further comprising, prior to the connection step, flipping an assembly formed by the first electronic chip, the second electronic chip, and the interconnection circuit so that the interconnection circuit faces the connection substrate and the connection pads of the first and second electronic chips are oriented towards the connection substrate.
